(19) United States
(12) Patent Application Publication
(10) Pub. No.: US 2025/0218914 A1
(43) Pub. Date: Jul. 3, 2025

(54) PACKAGE WITH COMPONENT-CARRYING INTERMEDIATE STRUCTURE AND ADDITIONAL CARRIER HAVING REFERENCE POTENTIAL STRUCTURE

(71) Applicant: Infineon Technologies AG, Neubiberg (DE)

(72) Inventors: Hao ZHUANG, Hohenbrunn (DE); Josef HÖGLAUER, Kirchheim-Heimstetten (DE); Milad MOSTOFIZADEH, München (DE); Markus DINKEL, Unterhaching (DE); Angela KESSLER, Sinzing (DE)

(73) Assignee: Infineon Technologies AG, Neubiberg (DE)

(21) Appl. No.: 18/977,320

(22) Filed: Dec. 11, 2024

(30) Foreign Application Priority Data
Dec. 27, 2023 (DE) 10 2023 136 713.7

(51) Int. Cl. H01L 23/498; H01L 21/56; H01L 23/00; H01L 23/367; H01L 23/495; H01L 25/18

(52) U.S. Cl. CPC H01L 23/49833; H01L 21/56; H01L 23/3672; H01L 23/49562; H01L 24/40; H01L 24/48; H01L 23/49503; H01L 23/49579; H01L 24/41; H01L 24/49; H01L 25/18; H01L 2224/40091; H01L 2224/40225; H01L 2224/40245; H01L 2224/4103; H01L 2224/48091; H01L 2224/48225; H01L 2224/48245; H01L 2224/4903; H01L 2924/13091

(57) ABSTRACT

A package is disclosed. In one example, the package includes an at least partially electrically conductive carrier having a coupling structure and a reference potential structure which is electrically decoupled from the coupling structure and which is configured to be brought to an electric reference potential during operation of the package, an intermediate structure at the carrier and having an electrically insulating structure oriented towards the carrier and having a mounting structure facing away from the carrier. An electronic component is mounted on the mounting structure and being electrically coupled with the coupling structure. An encapsulant is encapsulating at least part of the intermediate structure, at least part of the electronic component, and part of the carrier so as to expose at least part of the reference potential structure and at least part of the coupling structure.

### CROSS-REFERENCE TO RELATED APPLICATION

This Utility Patent Application claims priority to German Patent Application No. 10 2023 136 713.7 filed Dec. 27, 2023, which is incorporated herein by reference.

### BACKGROUND

### Technical Field

Various embodiments relate generally to a package, an electronic device, and a manufacturing method.

### Description of the related art

A conventional package may comprise a semiconductor component mounted on a carrier such as a leadframe structure, may be electrically connected by a bond wire extending from the semiconductor component to the carrier, and may be molded using a mold compound as an encapsulant.

Electric reliability of such a package may be an issue.

### SUMMARY

There may be a need for a package with high electric reliability.

According to an exemplary embodiment, a package is provided which comprises an at least partially electrically conductive carrier having a coupling structure and a reference potential structure which is electrically decoupled from the coupling structure and which is configured to be brought to an electric reference potential during operation of the package, an intermediate structure at the carrier and having an electrically insulating structure oriented towards the carrier and having a mounting structure facing away from the carrier, an electronic component mounted on the mounting structure and being electrically coupled with the coupling structure, and an encapsulant encapsulating at least part of the intermediate structure, at least part of the electronic component, and part of the carrier so as to expose at least part of the reference potential structure and at least part of the coupling structure.

According to another exemplary embodiment, an electronic device is provided which comprises a package having the above mentioned features, and an assembly structure assembled with the package.

According to still another exemplary embodiment, a method of manufacturing a package is provided, wherein the method comprises providing an at least partially electrically conductive carrier with a coupling structure and with a reference potential structure which is electrically decoupled from the coupling structure and which is configured to be brought to an electric reference potential during operation of the package, arranging at the carrier an intermediate structure with an electrically insulating structure oriented towards the carrier and with a mounting structure facing away from the carrier, mounting an electronic component on the mounting structure, electrically coupling the electronic component with the coupling structure, and encapsulating by an encapsulant at least part of the intermediate structure, at least part of the electronic component, and part of the carrier so as to expose at least part of the reference potential structure and at least part of the coupling structure.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates a cross-sectional view of an electronic device with a package according to an exemplary embodiment.

FIG. 2 to FIG. 4 illustrate three-dimensional views of structures obtained during manufacturing a package according to another exemplary embodiment.

### DETAILED DESCRIPTION

According to an exemplary embodiment, a package is provided which comprises an at least partially electrically conductive carrier having a coupling structure and a reference potential structure which is electrically decoupled from the coupling structure and which is configured to be brought to an electric reference potential during operation of the package, an intermediate structure at the carrier and having an electrically insulating structure oriented towards the carrier and having a mounting structure facing away from the carrier, an electronic component mounted on the mounting structure and being electrically coupled with the coupling structure, and an encapsulant encapsulating at least part of the intermediate structure, at least part of the electronic component, and part of the carrier so as to expose at least part of the reference potential structure and at least part of the coupling structure.

According to another exemplary embodiment, an electronic device is provided which comprises a package having the above mentioned features, and an assembly structure assembled with the package.

According to still another exemplary embodiment, a method of manufacturing a package is provided, wherein the method comprises providing an at least partially electrically conductive carrier with a coupling structure and with a reference potential structure which is electrically decoupled from the coupling structure and which is configured to be brought to an electric reference potential during operation of the package, arranging at the carrier an intermediate structure with an electrically insulating structure oriented towards the carrier and with a mounting structure facing away from the carrier, mounting an electronic component on the mounting structure, electrically coupling the electronic component with the coupling structure, and encapsulating by an encapsulant at least part of the intermediate structure, at least part of the electronic component, and part of the carrier so as to expose at least part of the reference potential structure and at least part of the coupling structure.

According to an exemplary embodiment, a package is equipped with a carrier having at least an electrically conductive part. Said carrier is provided with a coupling structure for accomplishing an electric coupling of an electronic component and, and separate therefrom, a reference potential structure to be set to an electric reference potential, such as a ground potential. Advantageously, an intermediate structure may be attached on one side to the carrier and on an opposing other side to one or more electronic components, such as at least one semiconductor chip, to be coupled with the coupling structure. An encapsulant, such as a mold compound, may encapsulate the intermediate structure, the electronic component, and the carrier. However, in particular the latter may be partially exposed beyond the encapsulant so that the reference potential structure may be connected to the reference potential and the coupling structure may be accessible from an exterior of the package for electrically coupling the package with an electronic environment. By the separate provision of, on the one hand, the carrier for accomplishing the electric coupling and for providing an electric reference potential, and, on the other hand, the intermediate structure for assembly of at least one electronic component and for mounting on the carrier, a compact package may be provided which provides high reliability and EMI (electromagnetic interference) protection. EMI may denote an electric disturbance that may affect the package by phenomena such as electromagnetic induction, electrostatic coupling, and/or conduction. By the EMI protection of the package due to the provision of the carrier with exposed reference potential structure in particular on a top side, a degradation of the performance of the package or even its stopping from functioning due to electromagnetic interference may be reliably prevented. At the same time, the described package architecture may ensure a simple manufacturing method and a compact design.

### DESCRIPTION OF FURTHER EXEMPLARY EMBODIMENTS

In the following, further exemplary embodiments of the package, the electronic device and the method will be explained.

In the context of the present application, the term “package” may particularly denote an arrangement which may comprise one or more packaged electronic components. A partially or entirely electrically conductive carrier may form part of the package as well. Said constituents of the package may be encapsulated at least partially by an encapsulant. Optionally, one or more electrically conductive connection elements (such as metallic pillars, pumps, bond wires and/or clips) may be implemented in a package, for instance for electrically coupling and/or mechanically supporting the electronic component.

In the context of the present application, the term “carrier” may particularly denote a support structure (which may be at least partially electrically conductive) which serves as a mechanical support in a package, and which may also contribute to the electric interconnection between one or more electronic components and the periphery of the package. In other words, the carrier may fulfil a mechanical support function and/or an electric connection function. A carrier may comprise or consist of a single part, multiple parts joined via encapsulation or other package components, or a subassembly of carriers. When the carrier forms part of a leadframe, it may be or may comprise a die pad. Also at least part of the carrier may be encapsulated by an encapsulant, together with the electronic component.

In the context of the present application, the term “reference potential” may particularly denote a well-defined or constant electric potential. Said electric potential may be for example an electric ground potential or a constant electric potential above or below ground potential. A reference potential may differ from a floating potential in that it may be pre-defined rather than arbitrary or uncontrolled.

In the context of the present application, the term “intermediate structure” may in particular denote a body which may be arranged as an electrically and/or mechanical interface between two other structures, in particular a carrier on one side and at least one electronic component on the other side. For instance, such a carrier may be a DAB (Direct Aluminum Bonding) Substrate, a DCB (Direct Copper Bonding) Substrate, etc. Moreover, the intermediate structure may also be configured as Active Metal Brazing (AMB) Substrate, or may comprise a leadframe structure (for instance made of copper), etc. Generally, a preferred embodiment of an intermediate structure is an electrically insulating and thermally conductive sheet or plate (for instance a ceramic sheet or plate) covered on both opposing main surfaces thereof with an electrically conductive layer (for instance a continuous or patterned metallic layer, for instance made of copper or aluminum).

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor, a temperature sensor or a gas sensor), an actuator (for instance a loudspeaker), and a microelectromechanical system (MEMS). However, in other embodiments, the electronic component may also be of different type, such as a mechatronic member, in particular a mechanical switch, etc. In particular, the electronic component may be a semiconductor chip having at least one integrated circuit element (such as a diode or a transistor in a surface portion thereof. The electronic component may be a bare die or may be already packaged or encapsulated. Semiconductor chips implemented according to exemplary embodiments may be formed for example in silicon technology, gallium nitride technology, silicon carbide technology, etc.

In the context of the present application, the term “encapsulant” may particularly denote a material, structure or member surrounding or intended for surrounding at least part of an electronic component and at least part of a carrier of a package. In this context, an encapsulant may provide mechanical protection and electrical insulation, and optionally a contribution to heat removal during operation. In particular, said encapsulant may be electrically insulating, for instance a mold compound. A mold compound may comprise a matrix of flowable and hardenable resin material, optionally one or more additives, and filler particles embedded therein. For instance, filler particles may be used to adjust the properties of the mold component, in particular to enhance thermal conductivity. As an alternative to a mold compound (for example on the basis of epoxy resin), the encapsulant may also be a potting compound (for instance on the basis of a silicone gel). Also a laminate-type encapsulant is possible.

In the context of the present application, the term “electronic device” may particularly denote a device with electronic functionality and which may comprise a package with one or more electronic components and an encapsulated carrier with exposed electrically conductive structure(s). The electronic device may have a mounting base carrying said package and/or a heat sink mounted on the package, i.e. at least one assembly structure.

In the context of the present application, the term “assembly structure” may particularly denote a structure being electrically and/or mechanically connected with the package. For instance, such an assembly structure may comprise a mounting base (which may be, for example, a printed circuit board (PCB)). The package may be surface mounted on the mounting base. Additionally or alternatively, the assembly structure may comprise a heat sink attached to the package for removing heat generated by the package, for instance predominantly generated by the at least one electronic component of the package, during operation.

In an embodiment, the carrier is a leadframe structure. In the context of the present application, the term “leadframe” may particularly denote a sheet-like metallic structure which can be bent, punched and/or patterned so as to form leadframe structures as mounting sections for mounting chips, and connection leads for electric connection of the package to an electronic environment. In an embodiment, the leadframe may be a metal plate (in particular made of copper) which may be patterned, for instance by stamping. Forming the carrier as a leadframe structure is a cost-efficient and mechanically as well as electrically highly advantageous configuration in which a low ohmic connection of chips can be combined with a robust support capability of the leadframe. Furthermore, a leadframe may contribute to the thermal conductivity of the package and may remove heat generated during operation of the chip(s) as a result of the high thermal conductivity of the metallic (in particular copper) material of the leadframe.

Particularly for the purposes of the carrier of exemplary embodiments, the use of a leadframe structure may be of utmost advantage. Such a leadframe structure may comprise the coupling structure which may function as at least one lead for accomplishing an exterior contact of the package, and the reference potential structure ensuring EMI protection or compliance by being connectable or connected to an electric reference potential such as ground. A leadframe structure is a simple and lightweight structure which may allow to realize a corresponding package with low space consumption.

In an embodiment, the carrier is a patterned and bent metallic plate. By patterning the metal plate, the coupling structure and the reference potential structure may be separated physically and electrically so that they are enabled to provide their dedicated electric functions. By optionally bending the metallic plate, leads may be bent and thereby oriented towards a mounting base of the package. A metallic plate is a simple and compact way of forming the carrier.

In an embodiment, the coupling structure comprises one or a plurality of electrically conductive leads. In the context of the present application, the term “leads” may particularly denote electrically conductive structures which may be electrically coupled with the electronic component(s) and/or the intermediate structure for enabling exterior access to the electronic component when the latter is encapsulated. For example, such leads or pins may be gullwing-shaped.

In an embodiment, the reference potential structure comprises a plate section with a main surface exposed beyond the encapsulant and comprises a lead section for connection with a mounting base for providing the electric reference potential. Preferably, the plate section and the lead section may be integrally formed, for instance as an integral section of a common structured metal plate. Descriptively speaking, the plate section may be a die pad of a leadframe structure-type reference potential structure. The plate section may provide a large area which, when exposed beyond the encapsulant, may function for attaching a heat sink to the plate section. This may bring the heat sink to the reference potential, for instance to ground potential. Furthermore, this may lead to a highly efficient dissipation of heat generated by the at least one encapsulated electronic component during operation of the package. For instance, the exposed plate section may allow for a top side cooling of the package. For this purpose, it may be advantageous if the exposed main surface area of the plate section is at least 10 times of the area of the reference potential structure and/or of the coupling structure.

In an embodiment, the electric reference potential is a ground potential or mass potential. The reference potential structure being at ground potential may denote a point where the electric potential is zero, i.e. it may be earthed. However, the electric reference potential may be any other electric potential as long as it is a reference potential, i.e. has a predefined or constant value (such as +2V or −6V).

In an embodiment, the mounting structure comprises a plurality of mutually electrically decoupled electrically conductive mounting sections. For example, the mounting sections may be separate islands of a metallic layer being patterned. When the mounting structure comprises plural electrically conductive mounting sections, this may allow to mount a plurality of electronic components each on a corresponding mounting section of the mounting structure which may be electrically decoupled from each other. A desired electric coupling between said electronic components may then be accomplished by one or more electrically conductive connection elements, such as bond wires or clips. The described configuration may allow to realize even complex electronic functionality provided by a plurality of electronic components of the package. This may be possible in a simple and compact way by forming the plurality of electrically decoupled electrically conductive mounting sections as separate sections of a common metallic layer.

In an embodiment, the intermediate structure has a further mounting structure facing the carrier and being electrically conductive so that the electrically insulating structure is arranged between the mounting structure and the further mounting structure. Said further mounting structure may be metallic, which may simplify a mechanical connection between the preferably also metallic carrier and the further mounting structure and which may optionally also allow to form an electrically conductive connection between carrier and mounting structure.

In an embodiment, the further mounting structure is connected with the reference potential structure. This may be accomplished by assembling the further mounting structure of the intermediate structure with the at least partially electrically conductive carrier. A corresponding connection may be carried out for instance by soldering or sintering.

In an embodiment, the intermediate structure comprises one of a Direct Copper Bonding (DCB) Substrate, a Direct Aluminum Bonding (DAB) Substrate, an Active Metal Brazing (AMB) Substrate, and an Insulated Metal Substrate (IMS). Generally, the intermediate structure may preferably comprise an electrically insulating and thermally conductive sheet (for instance made of ceramic) with an electrically conductive layer on one main surface thereof. Said electrically conductive layer may form the mounting structure, and may be preferably patterned to form a plurality of separate mounting sections. Preferably but not necessarily, a further electrically conductive layer may be arranged on the opposing other main surface of the electrically insulating and thermally conductive sheet, for simplifying connection with the carrier. Advantageously, an electrically insulating and thermally conductive layer of the intermediate structure may promote efficient dissipation of heat from the encapsulated electronic component(s) through the intermediate structure and the carrier towards an exterior of the package while ensuring simultaneously an electric decoupling of said at least one electronic component.

In an embodiment, the electronic component is electrically coupled with the mounting structure, the latter being electrically conductive. More specifically, one or more electrically conductive pads of the electronic component may be directly electrically coupled with the electrically conductive mounting structure of the intermediate structure, for instance by soldering or sintering.

In an embodiment, the package comprises at least one electrically conductive connection structure, for example at least one bond wire and/or at least one clip, electrically coupling the electronic component with the coupling structure and/or with the mounting structure. Such at least one electrically conductive connection structure may comprise a clip, a bond wire and/or a bond ribbon. A clip may be a curved or planar electrically conductive plate body accomplishing an electric connection with a high connection area to a main surface of a respective electronic component. Additionally or alternatively to such a clip, it is also possible to implement one or more other electrically conductive connection structures in the package, for instance at least one bond wire and/or at least one bond ribbon connecting the electronic component(s) with the carrier and/or the intermediate structure.

In an embodiment, the package comprises at least one further electronic component mounted on the mounting structure and being electrically coupled with the coupling structure and/or with the mounting structure. For example, the package may comprise one, two, three, four, five or more electronic components mounted on the intermediate structure. While in one embodiment, the package comprises only a single electronic component, the package may comprise alternatively a plurality of electronic components. For instance, such electronic components may be arranged side-by-side on the intermediate structure. Different electronic components may be of the same type or of different types. Different electronic components may have the same size or different sizes. For instance, the different electronic components may be semiconductor chips, in particular power semiconductor chips. It is for instance possible to provide a mixture of at least one IGBT-type electronic component and at least one silicon carbide-type electronic component.

In an embodiment, the intermediate structure is directly connected between the carrier and the electronic component. For instance, the intermediate structure may be connected between the carrier and the electronic component by soldering and/or sintering.

In an embodiment, the package is configured as control circuitry for controlling a solar panel, as telecommunications package, or as automotive package. For a solar panel, a control circuitry may be provided which may be formed by the intermediate structure, the carrier and electronic components, as well as one or more electrically conductive connection structures in between. In an automotive package, it is for instance possible that a converter function is provided by the package, for instance a one-phase or three-phase converter function. In telecommunications applications, a corresponding package may be included for instance in a mobile phone or in a base station. Other applications are of course possible.

In an embodiment, the assembly structure comprises a heat sink mounted on the package so that the exposed reference potential structure is thermally coupled with the heat sink. In the context of the present application, the term “heat sink” may in particular denote a highly thermally conductive body which may be thermally coupled with the exposed carrier of the package for removing heat generated by the electronic component(s) during operation of the package. For example, the heat sink may be made of a material having a thermal conductivity of at least 10 W/mK, in particular at least 50 W/mK, even up to 400 W/mK or even above. For instance, the heat sink may be made of an electrically conductive material such as copper and/or aluminum, but may also comprise a ceramic material. The heat sink may be directly or indirectly thermally coupled with the partially exposed carrier, for instance by a thermally conductive and electrically insulating layer, such as a thermal interface material (TIM) and/or a gap filler. For instance, the thermally conductive and electrically insulating layer may have a thermal conductivity in a range from 3 W/mK to 20 W/mK, or even above. For example, the heat sink may comprise a thermally conductive body (such as a metal plate) with a plurality of cooling fins extending from the thermally conductive body. Additionally or alternatively, liquid and/or gas cooling may be accomplished by a heat sink as well. The thermal coupling of the package with a heat sink may ensure an efficient cooling.

In an embodiment, the assembly structure comprises a mounting base, for example a laminate board, on which the package is mounted. For instance, the mounting base may be a printed circuit board (PCB), an Insulated Metal Substrate (IMS), a Direct Copper Bonding (DCB) Substrate or an Active Metal Brazing (AMB) substrate. As an alternative to a printed circuit board, also another kind of laminate carrier may be implemented as mounting base.

For instance, the package may be sandwiched between a mounting base and a heat sink.

In an embodiment, at least one electrically conductive contact terminal of the mounting base is electrically coupled with the coupling structure. Thus, the mounting base may comprise one or more electrically conductive pads or terminals which may be electrically coupled with the coupling structure. Thereby, the mounting base and the package may functionally cooperate for fulfilling a common electronic task.

In an embodiment, an electrically conductive reference potential terminal of the mounting base is electrically coupled with the reference potential structure to bring the reference potential structure to an electric reference potential of the mounting base. Said electrically conductive reference potential terminal can be a dedicated electrically conductive pad of the mounting base which lies at the reference potential, for instance may be grounded. The reference potential terminal and the reference potential structure may be electrically coupled by an electrically conductive connection medium, such as a solder or sinter material.

In an embodiment, the electronic component is a semiconductor power chip. Thus, the semiconductor component (such as a semiconductor chip) may be used for power applications (for instance in the automotive field) and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide or gallium nitride). A semiconductor power chip may comprise one or more field effect transistors, diodes, inverter circuits, half-bridges, full-bridges, drivers, logic circuits, further devices, etc.

In an embodiment, the package is a power package. In an embodiment, the package is configured as power module, for instance molded power module such as a semiconductor power package. For example, an exemplary embodiment of the package may be an intelligent power module (IPM). Another exemplary embodiment of the package is a dual inline package (DIP).

In an embodiment, the package is configured as one of the group consisting of a leadframe connected power module, a Transistor Outline (TO) package, a Quad Flat No Leads Package (QFN) package, a Small Outline (SO) package, a Small Outline Transistor (SOT) package, a Thin Small Outline Package (TSOP) package, and a Quadrupole Discrete Packaging (QDPAK) package. Also packages for sensors and/or mechatronic devices are possible embodiments. Moreover, exemplary embodiments may also relate to packages functioning as nano-batteries or nano-fuel cells or other devices with chemical, mechanical, optical and/or magnetic actuators. Therefore, the package according to an exemplary embodiment is fully compatible with standard packaging concepts (in particular fully compatible with standard TO packaging concepts) and appears externally as a conventional package, which is highly user-convenient.

In an embodiment, the package comprises a plurality of semiconductor components encapsulated by the semiconductor package encapsulant. Thus, the package may comprise one or more semiconductor components (for instance at least one passive component, such as a capacitor, and at least one active component). It is for instance also possible that the electronic component comprises a plurality of transistor chips and a control or driver chip.

As substrate or wafer forming the basis of the semiconductor component(s), a semiconductor substrate, in particular a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

Electromagnetic compatibility (EMC) may ensure that an electronic system, such as a package, can operate safely with sufficiently small or even minimal electric and electromagnetic interference. In order to comply with EMC requirements, power packages can be provided with an EMI (electromagnetic interference) shielding feature. However, this may be a challenging task due to other boundary conditions of package design.

In particular, conventional leadframe based discrete power packages do not offer EMI shielding capabilities. A user may need to do this shielding on board level, which may be cumbersome. Furthermore, this may only allow to provide an EMI protection at the bottom of the package. Thus, this may still lead to certain EMI from the top side of the package.

Suppressing EMI from the top side of the package would be very beneficial for a user to design a system for safe operation. This would offer a user the potential to increase the freedom of system design and to lower the effort in terms of EMI protection.

To achieve this, a shielding layer may have to be added to the top side and connected to ground. Technically, it may be difficult to provide such a structure with reasonable effort.

According to an exemplary embodiment, a package (which may be a semiconductor power package) may comprise a carrier and in addition an intermediate structure connected with the carrier. The partially or entirely electrically conductive carrier may for instance be a simple leadframe structure and may comprise a coupling structure for an electric coupling of the package with an electronic periphery, and a separate reference potential structure which may be brought to an electric reference potential, like for example electric ground potential, to thereby provide an electromagnetic interference (EMI) protection of the package, preferably at a top side of the package. The above-mentioned intermediate structure may be sandwiched between the carrier and an electronic component, for example a semiconductor power chip. The latter may be coupled with the coupling structure, for instance by an electrically conductive connection structure, such as a bond wire or a clip. A mold compound or another encapsulant may surround or encapsulate the intermediate structure, the electronic component, and part of the carrier. The carrier's reference potential structure may however be exposed and coupled with an electric reference potential (for instance provided from outside of the package), whereas the also exposed coupling structure may be coupled at an exterior surface of the package to an exterior electric entity. By the described interconnection of carrier and intermediate structure, a reliable EMI protection leading to a high electric reliability may combined with a high-performance, a simple and compact design as well as mechanical reliability.

In particular, an exemplary embodiment provides a top side cooled power package with top side EMI shielding. Topside cooling may be achieved by exposing a main surface of a plate section of the carrier's reference potential structure beyond the encapsulant for removing heat. Preferably, a heat sink may be attached to such a large-area exposed surface of the carrier.

According to exemplary embodiments, it may be possible to use a DCB or IMS board on the basis of a leadframe concept to fabricate a module with EMI shielding combined with a top side cooling feature. Such an architecture can be used, for example, for the fabrication of modules as well as discrete packages or half bridges.

In an embodiment, it may be possible to mount plural electronic components, such as integrated circuits, MOSFETs, sensors, diodes, etc., on top of a DCB. The DCB may be attached onto the leadframe die pad with die attach material (such as solder, glue, silver paste, etc.). The leadframe die pad may be electrically isolated from the electronic components by a ceramic sheet in the DCB. All leads except for at least one lead (which may be a ground lead or pin) may be electrically separated from the leadframe die pad. An electrical connection between the leads and electrical components may be established by wire bonding or clip bonding. A pin that electrically connects to the die pad may be soldered to a mounting base or board at ground potential to offer an EMI shielding feature from the top side. A heat sink can be attached to the exposed top side of the leadframe die pad which may be arranged, in turn, above and thermally coupled with the top side of the component(s) to enable top side cooling. Such a manufacturing architecture may enable an electrical isolation to the heat sink, and may also lead to an efficient heat dissipation to the heat sink.

For example, such a package or module can be fabricated by the following power module fabrication process: It may be possible to attach the intermediate structure (such as a DCB or an IMS) to the carrier (for instance a leadframe) by an electrically conductive connection medium, such as solder, glue, or silver paste. Furthermore, it may be possible to mount the electronic component(s) to the intermediate structure by die attach material. The one or more electronic components may then be electrically connected, for instance by wire bonding or clip mounting. This may be followed by encapsulating (for instance by molding). Readily manufactured packages may then be singulated. An obtained package may have a very similar exterior appearance as existing top side cooling TO packages, but with a feature of EMI shielding. Such a package may allow a user a simple handling without complexity in terms of EMI shielding at system level. The manufacturing effort may be reasonable, and system shrink may be possible. As a result, a DCB-on-leadframe package or module may be obtained offering EMI shielding combined with top side cooling.

According to an exemplary embodiment, a power package may be provided which may be fabricated based on a leadframe-type carrier and which may be provided with EMI shielding and topside cooling. For fabricating such a package (which may be embodied for example as a module, discrete, half bridge, power package, etc.), it may be possible to use an intermediate structure (such as a DCB or IMS board) to be arranged on a leadframe-type carrier enabling EMI shielding and topside cooling. The DCB or intermediate structure may be assembled with one or more electronic components (such as ICs, MOSFETs, sensors, diodes, etc.). The DCB with mounted electronic component(s) may be attached onto the carrier, preferably a leadframe die-pad of the carrier. This attachment may be accomplished using die attach material. The leadframe die-pad or carrier may be electrically insulated from the electronic component(s), for example by ceramic material in the intermediate structure. All the leads, except for at least one lead, may be electrically insulated from the leadframe die-pad of the carrier. An electrical connection between the lead and the electronic component(s) may be established, for example by wire or clip bonding. Advantageously, a pin connecting the die-pad may be connected (for instance soldered) to a ground potential of a mounting base (such as a board), providing EMI shielding on the top side. Preferably, a heat sink may be attached above the top of the electronic component(s) providing efficient top-side cooling with electrical isolation for the heat sink. A final fabrication process may be the formation of an encapsulation (for instance by molding), followed by singulation after performing mounting (for example using wire or clip bonding). As a result, a package with DCB design for EMI shielding may be obtained, wherein top side cooling may fulfill a reinforced insulation demand.

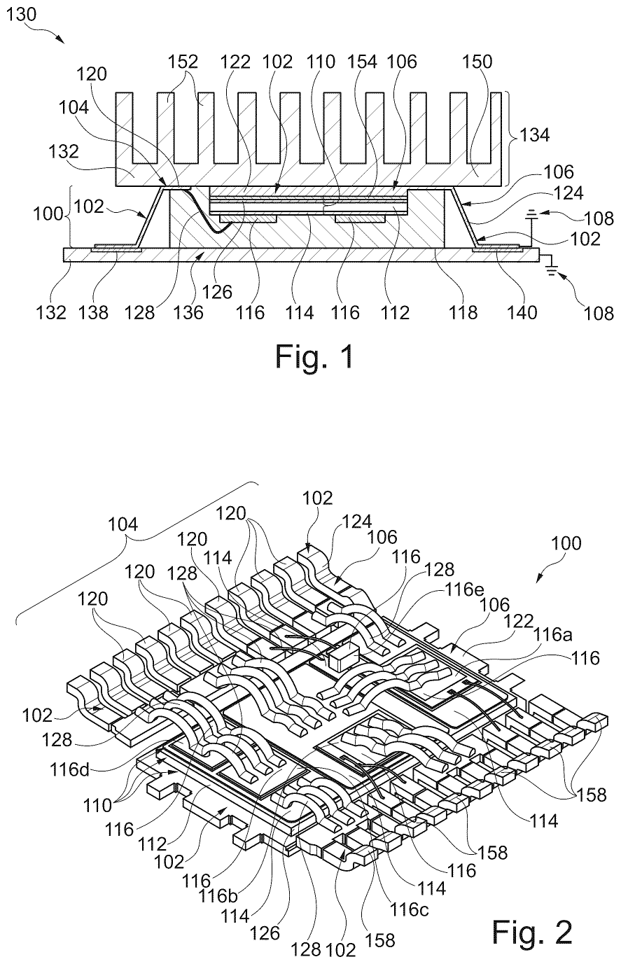

FIG. 1 illustrates a cross-sectional view of an electronic device 130 with a package 100 according to an exemplary embodiment. For example, the package 100 according to FIG. 1 may be configured as control circuitry for controlling a solar panel, whereas other electronic applications are possible as well.

The illustrated electronic device 130 comprises package 100 mounted between a bottom-sided mounting base 136 and a top-sided heat sink 134 of an assembly structure 132 assembled with the package 100. In the shown embodiment, the mounting base 136 may be a laminate carrier, such as a printed circuit board (PCB), which may collaborate electronically with the package 100. The heat sink 134 may comprise a thermally highly conductive cooling plate 150 which may be attached to the top side of the package 100, for instance with a thermal interface material (TIM) provided in between for enhancing thermal coupling (not shown). Furthermore, the heat sink 134 may comprise a plurality of cooling fins 152, which may extend from the cooling plate 150 with gaps in between for thermally transferring heat generated by electronic components 116 of package 100 towards an environment. For instance, heat sink 134 may be made of a highly thermally conductive material, such as aluminum. To put it shortly, heat sink 134 may remove heat generated by the electronic components 116 of the package 100 during operation.

The package 100 comprises an electrically conductive carrier 102, which may be a metallic leadframe, for instance made of copper. The electrically conductive carrier 102 may be a patterned and bent metal plate. As shown, the electrically conductive carrier 102 may have a coupling structure 104 and a reference potential structure 106.

The reference potential structure 106 is electrically decoupled from the coupling structure 104 and is configured to be brought to an electric reference potential 108 during operation of the package 100, such as ground potential. More precisely, the reference potential structure 106 is in fact brought to the electric reference potential 108 in the illustrated electronic device 130. For this purpose, the reference potential structure 106 is electrically coupled to an electrically conductive reference potential pad 140 of mounting base 136. More precisely, the reference potential structure 106 comprises a plate section 122 with a main surface exposed beyond an encapsulant 118 and comprises a bent lead section 124 for connection with the reference potential pad 140 of mounting base 136 for providing the electric reference potential 108. The reference potential structure 106 may comprise die pad-type or metal plate-type plate section 122 at reference potential and being exposed beyond the encapsulant 118 for providing highly efficient topside cooling. The reference potential structure 106 additional comprises lead section 124 being integrally formed with the plate section 122 but extending as a lead up to the bottom side of the package 100 for connection with mounting base 136. Thus, the reference potential structure 106 comprises plate section 122 with its upper main surface exposed beyond the encapsulant 118 and comprises the lead section 124 for connection with the mounting base 136 for providing the electric reference potential 108.

The coupling structure 104 can comprises one or a plurality of electrically conductive leads 120. Thus, the coupling structure 104 of the leadframe-type carrier 102 may be embodied as one or more leads 120 being also exposed beyond encapsulant 118 of the package 100 so as to be accessible from an exterior of the package 100. As shown, the coupling structure 104 extends as one or more bent leads up to the bottom side of the package 100 for connection with an electrically conductive contact terminal 138 of mounting base 136.

Additionally to the carrier 102, an intermediate structure 110 is assembled at the carrier 102, for instance by an electrically conductive connection medium 154 (such as solder or sinter material). As shown, the intermediate structure 110 is directly connected between the carrier 102 and electronic components 116. The intermediate structure 110 comprises a central electrically insulating structure 112 oriented towards the carrier 102 and being spaced with respect to the carrier 102 only by the electrically conductive connection medium 154 and an optional mounting structure 126 of the intermediate structure 110. Said insulating structure 112 is also thermally highly conductive, for instance is made of a ceramic material. Furthermore, the intermediate structure 110 comprises a mounting structure 114 facing away from the carrier 102 and being made of an electrically conductive material such as copper or aluminum. Beyond this, the intermediate structure 110 may comprise the already mentioned further mounting structure 126 facing the carrier 102 and being made of an electrically conductive material such as copper or aluminum. The insulating structure 112 is arranged between the mounting structure 114 and the further mounting structure 126. Thus, the intermediate structure 110 has a further mounting structure 126 facing the carrier 102 and being electrically conductive so that the electrically insulating structure 112 is arranged between the mounting structure 114 and the further mounting structure 126. By the electrically conductive connection medium 154, the further mounting structure 126 is connected with the carrier 102, more specifically with the plate section 122 of the carrier 102. Consequently, the further mounting structure 126 is connected with the reference potential structure 106 via the electrically conductive connection medium 154. For example, the described intermediate structure 110 may be embodied as a Direct Copper Bonding (DCB) Substrate, as a Direct Aluminum Bonding (DAB) Substrate, as an Insulated Metal Substrate (IMS), etc.

Additionally, package 100 comprises two (or any other number of) electronic components 116 each mounted on the mounting structure 114. Any smaller or larger number of electronic components 116 is possible in other embodiments. One of the illustrated electronic components 116 is electrically coupled with the coupling structure 104 by an electrically conductive connection structure 128, which is here embodied as a bond wire. Additionally or alternatively, any pad of any of the electronic components 116 may be electrically coupled with the mounting structure 114 via a further electrically conductive connection structure (not shown), such as a bond wire or a clip. For example, the electronic components 116 may be semiconductor chips, for instance power semiconductor chips.

Moreover, an encapsulant 118 is provided which fully encapsulates the intermediate structure 110, fully encapsulates the electronic components 116, fully encapsulates the electrically conductive connection structure 128, and only partially encapsulates the carrier 102. The only partial encapsulation of the carrier 102 is carried out so that the reference potential structure 106 and the coupling structure 104 are each partially exposed beyond the encapsulant 118. For example, the encapsulant 118 may be a mold compound. In another embodiment, the encapsulant 118 may be a laminate (for instance made of prepreg).

As already mentioned, the assembly structure 132 comprises the heat sink 134 which is mounted on top of the package 100 so that the exposed reference potential structure 106 and in particular its exposed plate section 122 is thermally coupled with the heat sink 134. More specifically, the entire large area of the exposed main surface of the grounded plate section 122 of the reference potential structure 106 is thermally and electrically coupled with the heat sink 134, which is thereby also grounded. Advantageously, this also provides a highly thermally conductive path from the encapsulated electronic components 116 (being the major heat sources of package 100 during operation) via the thermally highly conductive intermediate structure 110 and the thermally highly conductive electrically conductive connection medium 154 as well as via the thermally highly conductive plate section 122 of carrier 102 up to heat sink 134, and from there to the environment of the electronic device 130. Thus, the package 100 and the electronic device 130 as a whole are configured for highly efficient top side cooling while ensuring EMI protection. This allows to achieve a high performance and high electric power which can be handled safely by package 100.

On the bottom side of the electronic device 130, the assembly structure 132 comprises mounting base 136, which can be embodied as an organic laminate board such as a PCB. The package 100 is mounted on top of the mounting base 136. More specifically, one or more electrically conductive contact terminals 138, such as pads, of the mounting base 136 may be electrically coupled with the coupling structure 104. Furthermore, one or more electrically conductive reference potential terminals 140 of the mounting base 136 are electrically coupled with the exposed lead 124 of the reference potential structure 106 to bring the reference potential structure 106 to the electric reference potential 108 (here a ground potential) provided by the mounting base 136. This coupling to reference potential 108 (such as electric ground potential) provides the package 100 and the electronic device 130 as a whole with an electromagnetic interference (EMI) protection. The mentioned connections between leads 120, 124 of package 100 and pads 138, 140 of mounting base 136 may be established by an electrically conductive connection medium, such as solder or sinter material. It is optionally also possible that the bottom part of the encapsulant 118 is assembled on a main surface of mounting base 136 to further increase stability.

Summarizing, package 100 according to FIG. 1 provides efficient top side cooling. Furthermore, an electric shielding at the top side may also be enabled. Advantageously, the (for example MOSFET-type) electronic components 116 and the heat sink 134 may be electrically decoupled. Further advantageously, the heat sink 134 may be brought to the shielding potential.

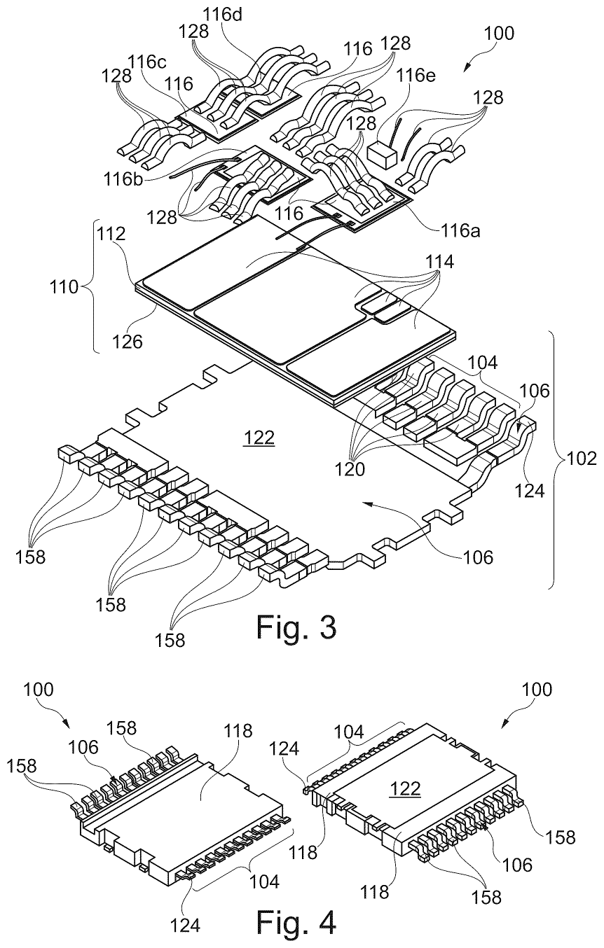

FIG. 2 to FIG. 4 illustrate three-dimensional views of structures obtained during manufacturing a package 100 according to another exemplary embodiment. More specifically, FIG. 2 shows an assembled state of constituents of the package 100 without encapsulant. FIG. 3 shows an exploded view of said package 100 without encapsulant. FIG. 4 shows a bottom view (left-hand side) and a top view (right-hand side of said package 100 after encapsulation by encapsulant 118, which can be a mold compound.

Referring to FIG. 2 and FIG. 3, an electrically conductive carrier 102 is provided as a leadframe structure, i.e. as a bent and structured metal plate (for instance made of copper). For example, a thickness of the leadframe-type carrier 102 may be in a range from 200 um to 1270 um, for example 500 um. Also a dual gauge design is possible in embodiments, meaning that leads and a die pad of carrier 102 may have different thicknesses. The carrier 102 is provided with a coupling structure 104 and with a reference potential structure 106 being electrically decoupled from the coupling structure 104.

The reference potential structure 106 is embodied as an integral metallic structure comprising a gullwing-shaped lead 124 and a die pad-type large-area plate section 122 integrally connected with lead 124. When mounted on a mounting base 136 (see FIG. 1), lead 124 may be electrically coupled with a terminal 140 of the mounting base 126 providing a reference potential 108 (such as a ground potential). Thus, lead 124 of reference potential structure 106 is configured to be brought to an electric reference potential 108 during operation of the package 100 and is to be mounted on mounting base 136. To put it shortly, lead 124 may be a ground pin. This ground pin forms part of the leadframe-type carrier 102 and is connected to the ground potential of the mounting base 136 to enable EMI shielding or protection. As shown in FIG. 2 to FIG. 4, plate section 122 may be electrically coupled with further leads 158.

The coupling structure 104 is embodied as a set of leads 120 being arranged side-by-side. As shown in FIG. 2, the leads 120 may be electrically coupled with electronic components 116 and an intermediate structure 110 by a set of electrically conductive connection structures 128, such as bond wires and/or clips.

Moreover, intermediate structure 110 is provided (such as a DCB or an IMS). As shown, intermediate structure 110 comprises, in the illustrated embodiment, a thermally conductive and electrically insulating structure 112 (for instance a ceramic sheet, for example made of aluminum oxide) having a mounting structure 114 on one main surface thereof and a further mounting structure 126 on the other main surface thereof. The thickness of the structure 112 may depend on the voltage class of package 100. For a 1200V voltage class, the thickness may be for example in a range from 100 μm to 200 μm. More generally, the thickness may be in a range from 50 μm to 800 μm. Mounting structures 114, 126 may be continuous or patterned metal layers (for instance may be made of aluminum). As best seen in FIG. 3, mounting structure 114 may comprise a plurality of separate mounting sections, for example five in the shown embodiment. Mounting structure 114 with its individual mounting sections may be denoted as the routing side of intermediate structure 110.

The manufacturing method may further comprise arranging the intermediate structure 110 at the carrier 102 so that the electrically insulating structure 112 is oriented towards the carrier 102 and so that the mounting structure 114 faces away from the carrier 102. Optional further mounting structure 126 may directly face the carrier 102 and may be connected with the plate section 122 of carrier 102 by electrically conductive connection medium, such as solder or sinter material. For instance, the DCB-type intermediate structure 110 may have a thickness of a central Al₂O₈ sheet of 380 μm with copper layers thereon which may have a thickness of for example 127 μm. It may be possible to attach the DCB-or IMS-type intermediate structure 110 to the leadframe-type carrier 102 for example by solder, glue, or silver paste.

Furthermore, a plurality of electronic components 116 may be assembled or mounted on the individual mounting sections of the mounting structure 114. Two electronic components 116a, 116b are embodied as transistor chips (more specifically as metal oxide semiconductor field-effect transistor (MOSFET) chips). During operation of the package 100, the electronic components 116a, 116b may be the main heat sources. Two further electronic components 116c, 116d may be embodied as diode chips. One additional electronic component 116e may be embodied as a passive component which may function as a temperature sensor. Of course, many other configurations of electronic components 116 may be possible depending on a specific electronic application.

After chip assembly, the manufacturing method may proceed with the formation of an electric coupling of the electronic components 116 with the leads 124 of the coupling structure 104, the mounting structure 114 and the leads 158 connected to the plate section 122 by a plurality of electrically conductive connection structures 128, see FIG. 2.

Referring to FIG. 4, the manufacturing method may then comprise encapsulating, by encapsulant 118, the intermediate structure 110, the electronic components 116, and part of the carrier 102 so as to expose part of the reference potential structure 106 (in the shown embodiment a main surface of plate section 122, lead 124 and leads 158) and part of the coupling structure 104 (in the shown embodiment leads 120). Thus, the obtained arrangement may be partially encapsulated by molding to thereby form mold compound-type encapsulant 118.

Still referring to FIG. 4, encapsulant 118 may be shaped for building a creepage current inhibiting feature (for instance embodied as a recess for spatially extending a creepage current path length).

In case of a batch manufacturing process for manufacturing a plurality of packages 100 in common, a singulation process may be executed at the end of the manufacturing process, for instance singulation by dicing.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A package, comprising:
an at least partially electrically conductive carrier having a coupling structure and a reference potential structure which is electrically decoupled from the coupling structure and which is configured to be brought to an electric reference potential during operation of the package;
an intermediate structure at the carrier and having an electrically insulating structure oriented towards the carrier and having a mounting structure facing away from the carrier;
an electronic component mounted on the mounting structure and being electrically coupled with the coupling structure; and
an encapsulant encapsulating at least part of the intermediate structure, at least part of the electronic component, and part of the carrier so as to expose at least part of the reference potential structure and at least part of the coupling structure.

2. The package according to claim 1, wherein the carrier is a leadframe structure.

3. The package according to claim 1, wherein the carrier is a patterned and bent metallic plate.

4. The package according to claim 1, wherein the coupling structure comprises one or a plurality of electrically conductive leads.

5. The package according to claim 1, wherein the reference potential structure comprises a plate section with a main surface exposed beyond the encapsulant and comprises a lead section for connection with a mounting base for providing the electric reference potential.

6. The package according to claim 1, wherein the electric reference potential is a ground potential.

7. The package according to claim 1, wherein the mounting structure comprises a plurality of mutually electrically decoupled electrically conductive mounting sections.

8. The package according to claim 1, wherein the intermediate structure has a further mounting structure facing the carrier and being electrically conductive so that the electrically insulating structure is arranged between the mounting structure and the further mounting structure.

9. The package according to claim 8, wherein the further mounting structure is connected with the reference potential structure.

10. The package according to claim 1, wherein the intermediate structure comprises one of a Direct Copper Bonding Substrate, a Direct Aluminum Bonding Substrate, an Active Metal Brazing Substrate, and an Insulated Metal Substrate.

11. The package according to claim 1, wherein the electronic component is electrically coupled with the mounting structure being electrically conductive.

12. The package according to claim 1, comprising at least one electrically conductive connection structure, for example at least one bond wire and/or at least one clip, electrically coupling the electronic component with the coupling structure and/or with the mounting structure.

13. The package according to claim 1, comprising at least one further electronic component mounted on the mounting structure and being electrically coupled with the coupling structure and/or with the mounting structure.

14. The package according to claim 1, wherein the intermediate structure is directly connected between the carrier and the electronic component.

15. The package according to claim 1, configured as control circuitry for controlling a solar panel, as telecommunications package, or as automotive package.

16. An electronic device, comprising:
a package according to claim 1; and
an assembly structure assembled with the package.

17. The electronic device according to claim 16, wherein the assembly structure comprises a heat sink mounted on the package so that the exposed reference potential structure is thermally coupled with the heat sink.

18. The electronic device according to claim 16, wherein the assembly structure comprises a mounting base on which the package is mounted.

19. The electronic device according to claim 18, comprising at least one of the following features:
wherein at least one electrically conductive contact terminal of the mounting base is electrically coupled with the coupling structure; and
wherein an electrically conductive reference potential terminal of the mounting base is electrically coupled with the reference potential structure to bring the reference potential structure to an electric reference potential of the mounting base.

20. A method of manufacturing a package, wherein the method comprises:
providing an at least partially electrically conductive carrier with a coupling structure and with a reference potential structure which is electrically decoupled from the coupling structure and which is configured to be brought to an electric reference potential during operation of the package;
arranging at the carrier an intermediate structure with an electrically insulating structure oriented towards the carrier and with a mounting structure facing away from the carrier;
mounting an electronic component on the mounting structure;
electrically coupling the electronic component with the coupling structure; and
encapsulating by an encapsulant at least part of the intermediate structure, at least part of the electronic component, and part of the carrier so as to expose at least part of the reference potential structure and at least part of the coupling structure.
